(19) United States
(12) Patent Application Publication
(10) Pub. No.: US 2025/0374599 A1
(43) Pub. Date: Dec. 4, 2025

(54) SOURCE/DRAIN CONTACTS

(71) Applicant: Taiwan Semiconductor Manufacturing Company, Ltd., Hsinchu (TW)

(72) Inventors: Yu-Lien Huang, Zhubei (TW); Yun-Hua Chen, Zhubei (TW); Yuan-Sheng Huang, Taichung (TW); Yung-Cheng Lu, Hsinchu (TW)

(73) Assignee: Taiwan Semiconductor Manufacturing Company, Ltd., Hsinchu (TW)

(21) Appl. No.: 18/733,737

(22) Filed: Jun. 4, 2024

(51) Int. Cl. H01L 29/417; H01L 21/285; H01L 29/06; H01L 29/08; H01L 29/40; H01L 29/423; H01L 29/66; H01L 29/775; H01L 29/786

(52) U.S. Cl. CPC H10D 30/6729; H01L 21/28518; H10D 30/014; H10D 30/031; H10D 30/43; H10D 30/6735; H10D 30/6757; H10D 62/121; H10D 62/151; H10D 64/01; H10D 64/017; H10D 64/018

(57) ABSTRACT

Provided are semiconductor structures and methods for fabricating semiconductor structures. A method includes forming a stack of semiconductor nanosheets over a substrate; forming a source/drain feature adjacent to the stack; etching a portion of the source/drain feature to form a trench, wherein the trench extends to a horizontal plane at or below a lowest surface of a lowest semiconductor nanosheet in the stack; and forming a conductive contact to the source/drain feature in the trench.

### BACKGROUND

The electronics industry has experienced an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). Thus far the demand has been met in large part by scaling down semiconductor IC dimensions (e.g., minimum feature size) and thereby improving production efficiency and lowering associated costs. However, such scaling has also introduced increased complexity to the semiconductor manufacturing process. Thus, the realization of continued advances in semiconductor ICs and devices calls for similar advances in semiconductor manufacturing processes and technology.

Multi-gate devices have been introduced in an effort to improve gate control by increasing gate-channel coupling, to reduce OFF-state current, and to reduce short-channel effects (SCEs). One such multi-gate device that has been introduced is the fin field-effect transistor (FinFET). The FinFET gets its name from the fin-like structure which extends from a substrate on which it is formed, and which is used to form the FET channel. Another multi-gate device, introduced in part to address performance challenges associated with FinFETs, is the gate-all-around (GAA) transistor. GAA devices get their name from the gate structure which extends completely around the channel, providing better electrostatic control than FinFETs. FinFET devices and GAA devices are compatible with conventional complementary metal-oxide-semiconductor (CMOS) processes. Further, the three-dimensional structure of such devices allows them to be aggressively scaled while maintaining gate control and mitigating SCEs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a plan view of a layout of a multi-gate device, in accordance with some embodiments.

FIG. 2 is a flow chart illustrating a method, in accordance with some embodiments.

FIGS. 3-24 are cross-sectional views of the semiconductor device during successive stages of fabrication according to the method of FIG. 2, in accordance with some embodiments.

### DETAILED DESCRIPTION

The following disclosure provides many different embodiments, or examples, for implementing different features of the subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “over”, “overlying”, “above”, “upper”, “top”, “under”, “underlying”, “beneath”, “below”, “lower”, “bottom”, “side”, and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In certain embodiments herein, a “material layer” is a layer that includes at least 50 wt. % of the identified material, for example at least 60 wt. % of the identified material, at least 75 wt. % of the identified material, or at least 90 wt. % of the identified material, or substantially 100 wt. % of the identified material; and a layer that is a “material” includes at least 50 wt. % of the identified material, for example at least 60 wt. % of the identified material, at least 75 wt. % of the identified material, or at least 90 wt. % of the identified material, or substantially 100 wt. % of the identified material. For example, certain embodiments, each of a titanium nitride layer and a layer that is titanium nitride is a layer that is at least 50 wt. %, at least 60 wt. %, at least 75 wt. %, titanium nitride, at least 90 wt. %, or at least 95 wt. %, or substantially 100 wt. %, titanium nitride.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

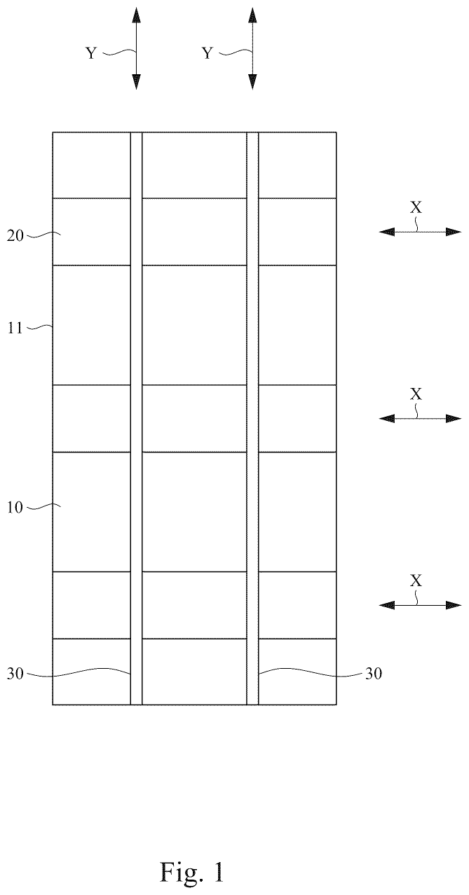

FIG. 1 illustrates a unit cell 11, i.e., a portion of the semiconductor substrate 10 in a semiconductor device 100. As shown, parallel active regions 20 are spaced apart from one another and extend in an X-direction. Further, parallel gate lines 30 are spaced apart from one another and extend in a Y-direction perpendicular to the X-direction. Exemplary gate lines 30 are formed from conductive material such as metal and form gate structures for the device 100.

The semiconductor device 100 may be a multi-gate device 100. In various embodiments, the multi-gate device 100 may include a FinFET device, a GAA transistor, or other type of multi-gate device. The multi-gate device 100 is formed over a substrate 10.

The multi-gate devices 100 may include a P-type metal-oxide-semiconductor device 100 or an N-type metal-oxide-semiconductor multi-gate device 100. Specific examples may be presented and referred to herein as FinFET devices 100, on account of their fin-like structure. Also presented herein are embodiments of a type of multi-gate transistor referred to as a gate-all-around (GAA) device 100. A GAA device 100 includes any device that has its gate structure, or portion thereof, formed on four sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Herein, the terms “nanosheet” or “nanosheet channel” are intended to include nanowire channel and bar-shaped channel configurations.

In some embodiments, the substrate 10 may be a semiconductor substrate such as a silicon substrate. The substrate 10 may include various layers, including conductive or insulating layers formed on a semiconductor substrate. The substrate 10 may include various doping configurations depending on design requirements as is known in the art. The substrate 10 may also include other semiconductors such as germanium, silicon carbide (SiC), silicon germanium (SiGe), or diamond. Alternatively, the substrate 10 may include a compound semiconductor and/or an alloy semiconductor. Further, the substrate 10 may optionally include an epi layer, may be strained for performance enhancement, may include a silicon-on-insulator (SOI) structure, and/or have other suitable enhancement features.

Presented herein are embodiments of devices that may have one or more channel regions (e.g., nanosheets) associated with a gate structure. For example, a stack of vertically spaced nanosheet channels may be provided. However, one of ordinary skill would recognize that the teaching can apply to a single channel (e.g., single nanosheet) or any number of channels. One of ordinary skill may recognize other examples of semiconductor devices that may benefit from aspects of the present disclosure.

In certain embodiments, a conductive contact is formed in contact with a source/drain feature. As used herein, “source/drain region(s)” or “source/drain feature(s)” may refer to a source or a drain, individually or collectively dependent upon the context.

Further, a conductive path from source/drain contact to a channel region, such as a nanosheet channel or stack of nanosheet channels is provided with reduced resistance. Specifically, methods herein provide a direct, shortest, conductive path from the source/drain contact to the channel regions. For example, in embodiments herein, portions of the source/drain features are recessed and source/drain contacts are formed directly adjacent to, and at the same height as, the nanosheet channel regions. For example, direct lateral, horizontal, paths from the source/drain contact to the nanosheet channels are provided. Further, the lateral distance between the source/drain contact and each nanosheet channel may be minimized by removing or reducing the amount of source/drain feature located between the source/drain contact and each nanosheet channel.

In certain embodiments, current cladding is prevented by the methods described herein. Thus, device performance is boosted or improved over devices in which current paths must travel vertically and horizontally through source/drain feature material between source/drain contacts and channel regions.

Embodiments of the present disclosure offer advantages over the existing art, though it is understood that other embodiments may offer different advantages, not all advantages are necessarily discussed herein, and no particular advantage is required for all embodiments.

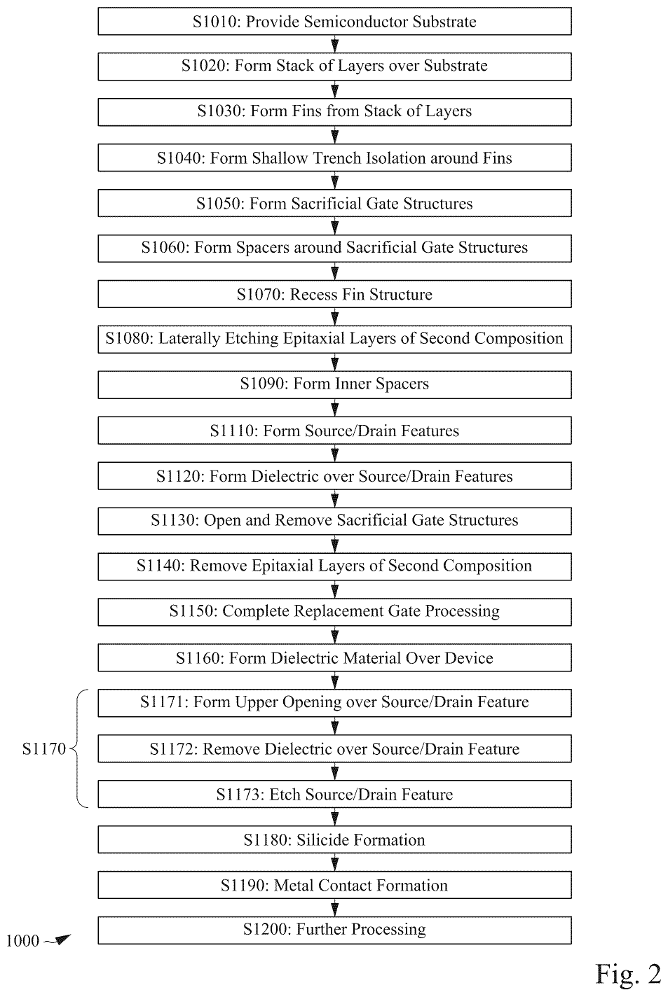

Referring to FIG. 2, illustrated therein is a method 1000 of fabrication of a semiconductor device 200 (such as a multi-gate device 100), in accordance with various embodiments. Method 1000 is discussed below with reference to a GAA device 200 having a channel region that may be referred to as a nanosheet or nanosheet channel and which may include various geometries (e.g., cylindrical, bar-shaped) and dimensions. However, it will be understood that aspects of method 1000 may be equally applied to other types of multi-gate devices without departing from the scope of the present disclosure. In some embodiments, method 1000 may be used to fabricate the multi-gate device 100, described above with reference to FIG. 1. Thus, one or more aspects discussed above with reference to the multi-gate device 100 may also apply to method 1000. It is understood that method 1000 includes steps having features of a complementary metal-oxide-semiconductor (CMOS) technology process flow and thus, are only described briefly herein. Also, additional steps may be performed before, after, and/or during method 1000.

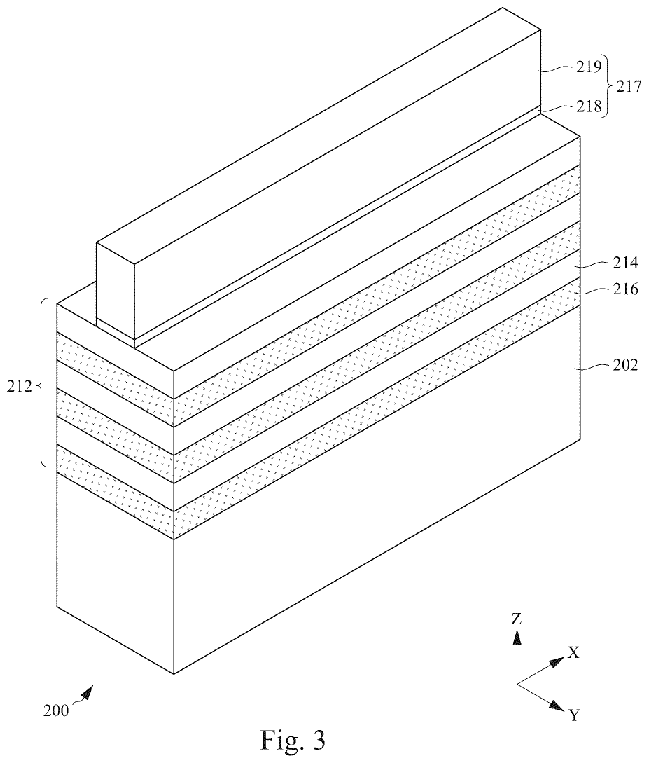

Method 1000 is described below with reference to FIGS. 3-25, which provide perspective views of the multi-gate device 200, cross-sectional views of the multi-gate device 200 along a plane substantially parallel to a plane defined by the X and Z axes in FIG. 1, and cross-sectional views of the multi-gate device 200 along a plane substantially parallel to a plane defined by the Y and Z axes in FIG. 1, as described, illustrating various stages of fabrication according to method 1000.

Further, the semiconductor device 200 may include various other devices and features, such as other types of devices such as additional transistors, bipolar junction transistors, resistors, capacitors, inductors, diodes, fuses, static random-access memory (SRAM) and/or other logic circuits, etc., but is simplified for a better understanding of the concepts of the present disclosure. In some embodiments, the semiconductor device 200includes a plurality of semiconductor devices (e.g., transistors), including PFETs, NFETs, etc., which may be interconnected. Moreover, it is noted that the process steps of method 1000, including any descriptions given with reference to the figures are merely exemplary and are not intended to be limiting beyond what is specifically recited in the claims that follow.

At operation S1010, the method 1000 provides a substrate 202, as shown in FIG. 3. In some embodiments, the substrate 202 may be a semiconductor substrate such as a silicon (Si) substrate. The substrate 202 may include various layers, including conductive or insulating layers formed on a semiconductor substrate. The substrate 202 may include various doping configurations depending on design requirements as is known in the art. For example, different doping profiles (e.g., p-well, n-well) may be formed on the substrate 202 in regions designed for different device types (e.g., n-type field effect transistors (NFET), p-type field effect transistors (PFET)). The suitable doping may include ion implantation of dopants and/or diffusion processes, such as boron (B) for the p-well and phosphorous (P) for the n-well. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. In the illustrated embodiment, the substrate 202 is made of crystalline Si.

As shown in FIG. 3, at operation S1020, the method 1000 (FIG. 2) forms one or more epitaxial layers over the substrate 202. In some embodiments, an epitaxial stack 212 is formed over the substrate 202. The epitaxial stack 212 includes epitaxial layers 214 of a first composition interposed by epitaxial layers 216 of a second composition. The first and second composition may be different. Embodiments are possible including those that provide for a first composition and a second composition having different oxidation rates and/or etch selectivity. In an embodiment, the epitaxial layers 216 are SiGe and the epitaxial layers 214 are silicon. In embodiments wherein the epitaxial layer 216 includes SiGe and the epitaxial layer 214 includes silicon, the silicon oxidation rate is less than the SiGe oxidation rate. It is noted that three layers of epitaxial layers 214 and three layers of epitaxial layers 216 are illustrated in FIG. 3, which is for illustrative purposes only and not intended to be limiting beyond what is specifically recited in the claims. It can be appreciated that any number of epitaxial layers may be formed in the epitaxial stack 212; the number of layers depending on the desired number of channels regions for the GAA device 200. In some embodiments, the number of epitaxial layers 216 is between two and ten, such as six or seven.

In some embodiments, the epitaxial layer 216 has a thickness ranging from about five nanometers to about fifteen nanometers. The epitaxial layers 216 may be substantially uniform in thickness. In some embodiments, the epitaxial layer 214 has a thickness ranging from about five nanometers to about fifteen nanometers. In some embodiments, the epitaxial layers 214 of the stack are substantially uniform in thickness. As described in more detail below, the epitaxial layer 214 may serve as channel region(s) for a subsequently formed multi-gate device and has a thickness chosen based on device performance considerations. The epitaxial layer 216 may serve to define a gap between adjacent channel region(s) for a subsequently formed multi-gate device and has a thickness chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers such as, the epitaxial layers 216 include the same material as the substrate 202. In some embodiments, the epitaxially grown layers 214 and 216 include a different material than the substrate 202. As stated above, in at least some examples, the epitaxial layer 216 includes an epitaxially grown Si₁₋ₓGeₓ layer (wherein x is from about 10 to about 55%) and the epitaxial layer 214 includes an epitaxially grown silicon (Si) layer. Alternatively, in some embodiments, either of the epitaxial layers 214 and 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GalnP, and/or GaInAsP, or combinations thereof. As discussed, the materials of the epitaxial layers 214 and 216 may be chosen based on providing differing oxidation, etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process. In some embodiments, the bottom layer and the top layer of the epitaxial stack 212 are SiGe layers (not shown). In alternative embodiments, the bottom layer of the epitaxial stack 212 is a Si layer and the top layer of the epitaxial stack 212 is a SiGe layer (not shown).

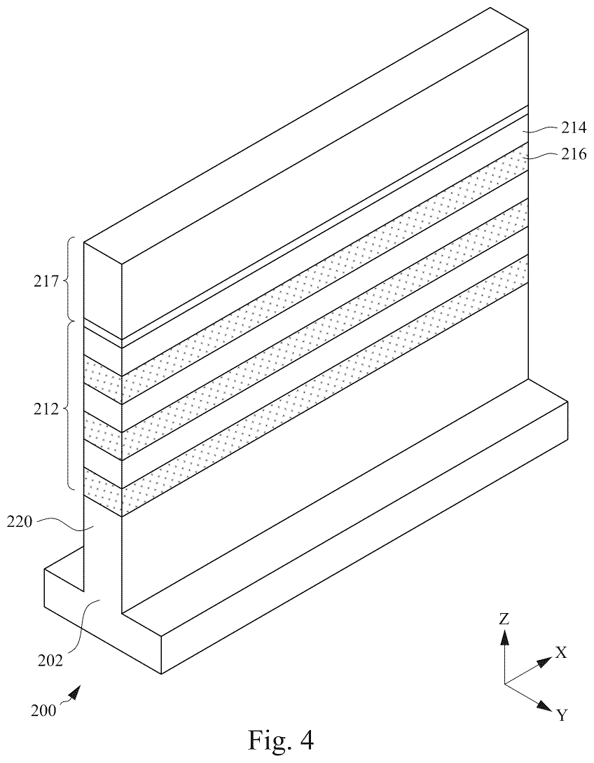

As shown in FIGS. 3-4, at operation S1030, the method 1000 (FIG. 2) patterns the epitaxial stack 212 to form a semiconductor fin 220. In some embodiments, the operation S1030 includes forming a mask layer 217 over the epitaxial stack 212, as shown in FIG. 3. The mask layer 217 includes a first mask layer 218 and a second mask layer 219. An exemplary first mask layer 218 is a pad oxide layer made of a silicon oxide, which may be formed by a thermal oxidation. An exemplary second mask layer 219 is made of a silicon nitride (SiN), which may be formed by chemical vapor deposition (CVD), including low pressure CVD (LPCVD) and plasma enhanced CVD (PECVD), physical vapor deposition (PVD), atomic layer deposition (ALD), or other suitable process. The mask layer 217 is patterned into a mask pattern by using patterning operations including photolithography and etching. Operation S1030 subsequently patterns the epitaxial stack 212 in an etching process, such as a dry etch (e.g., reactive ion etching), a wet etch, and/or other suitable process, through openings defined in the patterned mask layer 217. The stacked epitaxial layers 214 and 216 are thereby patterned into the fin 220. While FIG. 4 illustrates the formation of one fin 220, any suitable number of the fins may be formed. Trenches are etched between adjacent fins 220.

In various embodiments, each fin 220 includes an upper portion of the interleaved epitaxial layers 214 and 216, and a bottom portion that is formed from the etched substrate 202. Each fin 220 protrudes upwardly in the Z-direction from the substrate 202 and extends lengthwise in the Y-direction. Sidewalls of each fin 220 may be straight or inclined (not shown). In FIG. 4, additional fins would be spaced apart along the Y-direction. The fins 220 may have a same width or different widths.

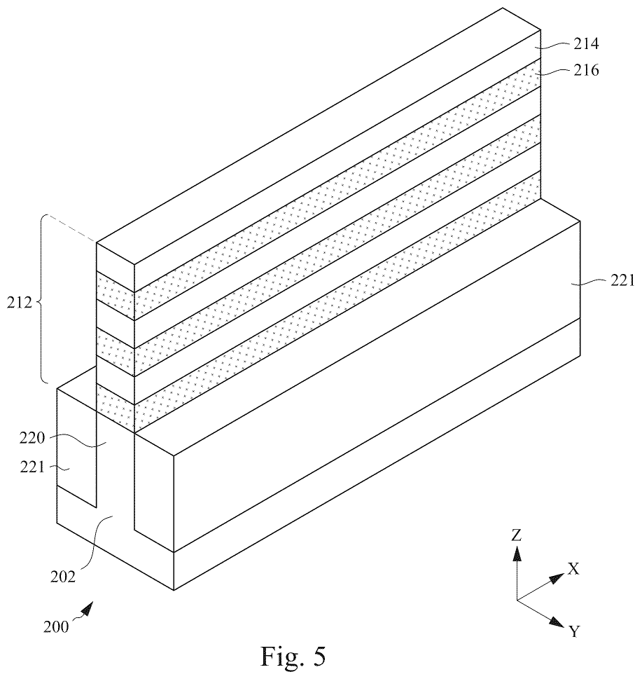

As shown in FIG. 5, at operation S1040, the method 1000 (FIG. 2) forms shallow trench isolation (STI) features (also denoted as STI features) 221 in trenches adjacent to each fin 220 with a dielectric layer. The STI features 221 may be formed by first filling the trenches around each fin 220 with a dielectric material layer to cover top surfaces and sidewalls of the fin 220 (not shown). The dielectric material layer may include one or more dielectric materials. Suitable dielectric materials for the dielectric layer may include silicon oxides, silicon nitrides, silicon carbides, fluorosilicate glass (FSG), low-K dielectric materials, and/or other suitable dielectric materials. The dielectric material may be deposited by any suitable technique including thermal growth, flowable CVD (FCVD), HDP-CVD, PVD, ALD, and/or spin-on techniques. The dielectric material layer is then planarized by using, for example, chemical mechanical planarization (CMP), until top surfaces of the mask layer 217 are revealed, and the dielectric material layer is recessed to form the shallow trench isolation (STI) features (also denoted as STI features) 221, as shown in FIG. 5. In the illustrated embodiment, the STI features 221 are formed on the substrate 202. Any suitable etching technique may be used to recess the isolation features 221 including dry etching, wet etching, RIE, and/or other etching methods, and in an exemplary embodiment, an anisotropic dry etching is used to selectively remove the dielectric material of the isolation features 221 without etching the fin 220. The mask layer 217 (shown in FIG. 4) may also be removed before, during, and/or after the recessing of the isolation features 221. In some embodiments, the mask layer 217 is removed by the CMP process performed prior to the recessing of the isolation features 221. In some embodiments, the mask layer 217 is removed by an etchant used to recess the isolation features 221.

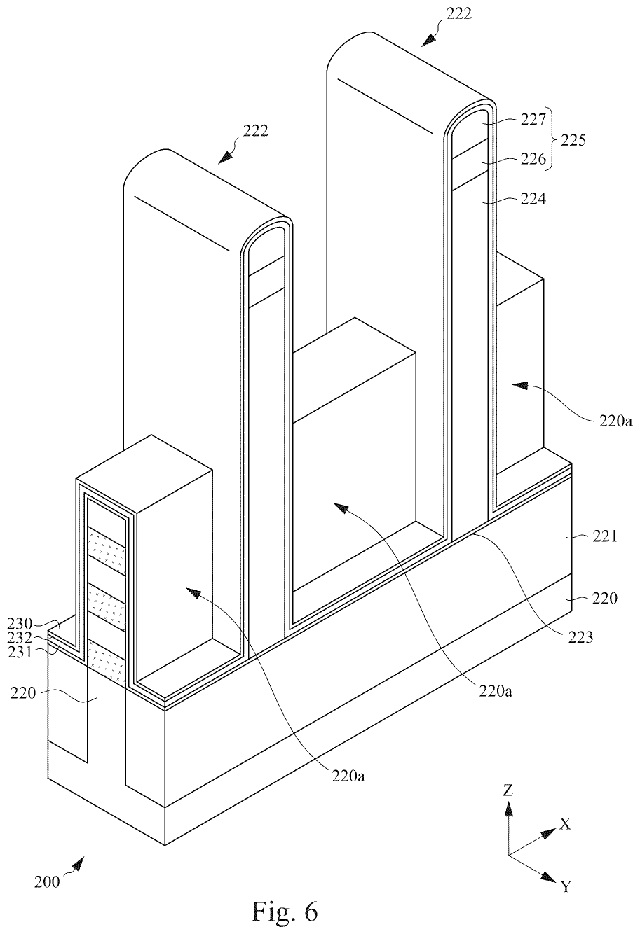

As shown in FIG. 6, at operation S1050, the method 1000 (FIG. 2) forms sacrificial (dummy) gate structures 222. The sacrificial gate structures 222 are formed over portions of the fin 220 which are to be channel regions. The sacrificial gate structures 222 may extend over a number of adjacent fins (not shown). The sacrificial gate structures 222 lie directly over and define the channel regions of the GAA devices to be formed. Each of the sacrificial gate structures 222 includes a sacrificial gate dielectric 223 and a sacrificial gate electrode 224 over the sacrificial gate dielectric 223. As shown, the gate structures 222 extend lengthwise in the Y-direction and are spaced apart in the X-direction.

The sacrificial gate structures 222 are formed by first blanket depositing a sacrificial gate dielectric layer over the fin(s) 220. A sacrificial gate electrode layer is then blanket deposited on the sacrificial gate dielectric layer and over the fin(s) 220. The sacrificial gate dielectric layer includes silicon oxide, silicon nitride, or a combination thereof. The thickness of the sacrificial gate electrode layer is in a range from about one hundred nanometers to about two hundred nanometers in some embodiments. The sacrificial gate electrode layer 224 includes silicon such as polycrystalline silicon or amorphous silicon. The thickness of the sacrificial gate dielectric layer is in a range from about one nanometer to about five nanometers in some embodiments. In some embodiments, the sacrificial gate electrode layer is subjected to a planarization operation. The sacrificial gate dielectric layer and the sacrificial gate electrode layer are deposited using CVD, including LPCVD and PECVD, PVD, ALD, or other suitable process. A mask layer 225 is formed over the sacrificial gate electrode layer. The mask layer 225 may include a mask layer 226 such as silicon oxide and a mask layer 227 such as silicon nitride. Subsequently, a patterning operation is performed on the mask layer 225, the sacrificial gate electrode layers and the sacrificial gate dielectric layer are patterned into the sacrificial gate structures 222, including sacrificial gate dielectric layer 223 and sacrificial gate electrode 224.

As shown, the fin 220 is partially exposed between and on opposite sides of the sacrificial gate structures 222, thereby defining source/drain (S/D) regions. In this disclosure, a source and a drain are interchangeably used and the structures thereof are substantially the same.

Still referring to FIG. 6, at operation S1060, the method 1000 (FIG. 2) forms spacers 230 on sidewalls of the sacrificial gate structures 222 and sidewalls of the fins 220 by depositing spacer materials, followed by an etching. The spacers 230 may include spacer material such as silicon oxide, silicon nitride, silicon carbide, silicon oxynitride, SiCN films, silicon oxycarbide, SiOCN films, and/or combinations thereof. In some embodiments, each of the spacers 230 include multiple layers, such as a liner layer 231 and a main spacer layer 232 on a sidewall of the liner layer 231.

By way of example, the spacers 230 may be formed by depositing spacer material including a liner material layer and a dielectric material layer over the sacrificial gate structure 222 using processes such as a subatmospheric CVD (SACVD) process, a flowable CVD process, an ALD process, a PVD process, or other suitable process respectively.

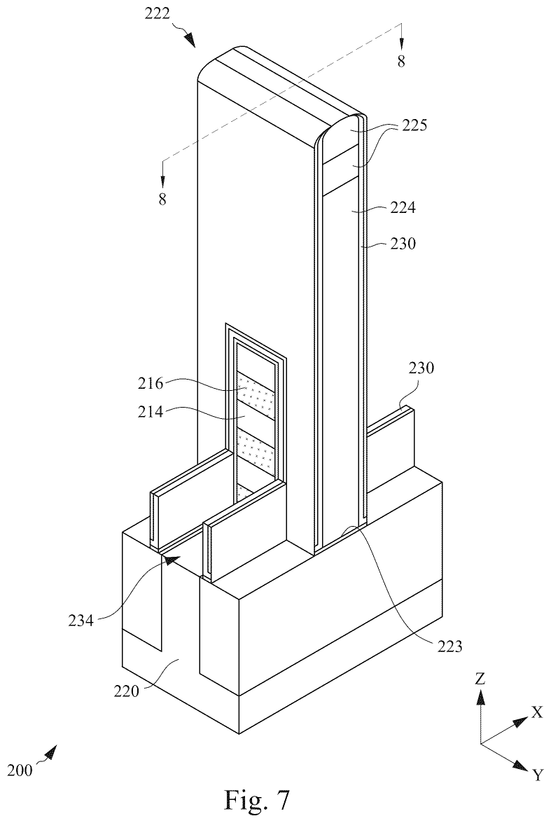

As shown in FIG. 7, the deposition of the liner material layer and the dielectric material layer are followed by, at operation S1070, etching-back (e.g., anisotropically) to expose, and remove, portions 220a of the fins 220 adjacent to and not covered by the sacrificial gate structure 222 (e.g., S/D regions). The liner material layer and the dielectric material layer may remain on the sidewalls of the sacrificial gate structure 222 as the gate sidewall spacers 230, and on the sidewalls of the fins as the fin sidewall spacers 230. In some embodiments, the etching-back process may include a wet etch process, a dry etch process, a multiple-step etch process, and/or a combination thereof. The spacers 230 may have a thickness ranging from about five nanometers to about twenty nanometers.

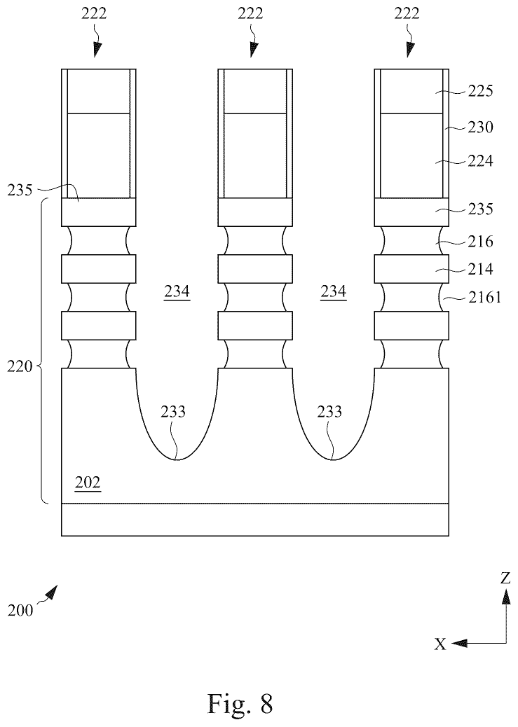

Cross-referencing FIG. 7 with FIG. 8, a cross-sectional view taken along line 8-8 in FIG. 7, i.e., an X-cut cross-sectional view, at operation S1070, the method 1000 (FIG. 2) recesses the portions of the fin 220 not covered by the sacrificial gate structures 222 to form gaps or recesses 234 in the S/D regions. It is noted that FIG. 7 shows only one sacrificial gate structure 222 and the adjacent portion of fin 220 so that etching of the S/D region between the sacrificial gate structures 222 of FIG. 6 may be more clearly viewed. FIG. 8 is a cross sectional-view along line 8-8 in FIG. 7 but illustrates three sacrificial gate structures 222 and a fin 220 lying under the sacrificial gate structures 222.

As shown most clearly in FIG. 8, the stacked epitaxial layers 214 and 216 are etched to a bottom gap surface 233 formed by the fin 220. In many embodiments, the operation S1070 forms the gaps 234 by a suitable etching process, such as a dry etching process, a wet etching process, or a combination thereof. As a result of the etching process, fin segments 235 of the upper portion of the fin 220 are defined and separated from one another by the gaps 234.

As further shown in FIG. 8, method 1000 (FIG. 2) includes laterally etching the epitaxial layers 216 of the second composition at operation S1080. In an exemplary embodiment, an SiGe etchback process is performed to laterally recess the layers 216. As a result, pockets 2161 are formed laterally adjacent to the layers 216 and vertically adjacent to the layers 214.

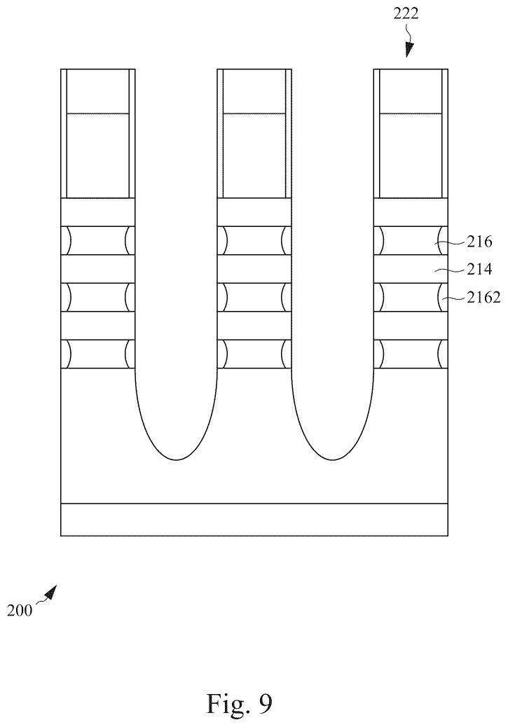

As shown in FIG. 9, method 1000 (FIG. 2) includes forming inner spacers 2162 in the pockets 2161 laterally adjacent to epitaxial layers 216 at operation S1090. FIG. 9 is an X-cut cross-sectional view. In exemplary embodiments, the inner spacers 2162 may be formed from silicon oxides, silicon nitrides, silicon carbides, silicon carbide nitride, silicon oxide carbide, silicon carbide oxynitride, and/or other suitable dielectric materials. The inner spacers 2162 may be formed by ALD or any other suitable method. As shown, after deposited the material forming inner spacers 2162, the material may be trimmed from the sidewalls of epitaxial layers 214.

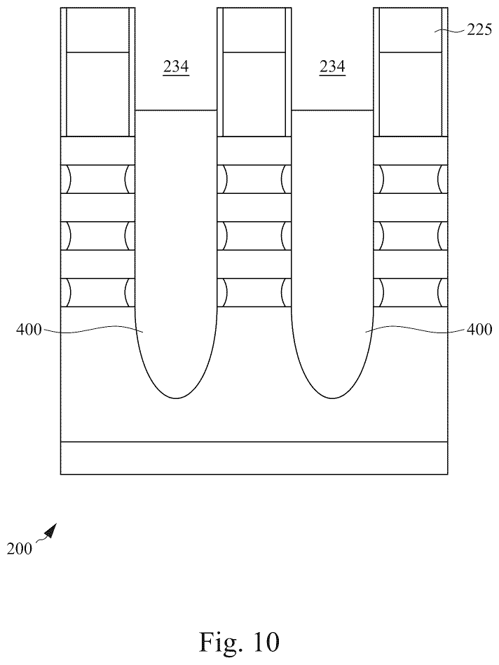

The method may continue, at operation S1110, with forming source/drain features 400, as shown in FIG. 10. FIG. 10 is an X-cut cross-sectional view. In exemplary embodiments, the source/drain features 400 are formed by epitaxial growth. For example, operation S1110 may include selectively growing epitaxial material over the isolation layer 300 to form source/drain features 400. In exemplary embodiments, the source/drain features 400 are strained source/drain features 400.

In exemplary embodiments, the source/drain features 400 may include an n-type epitaxial material source/drain features and a p-type epitaxial material source/drain features. The epitaxial material may include one or more layers of Si, SiP, SiC and SiCP for an n-channel FET or Si, SiGe, Ge for a p-channel FET. For the P-channel FET, boron (B) may also be contained in the source/drain. The source/drain epitaxial layers may be formed by an epitaxial growth method using CVD, ALD, or molecular beam epitaxy (MBE).

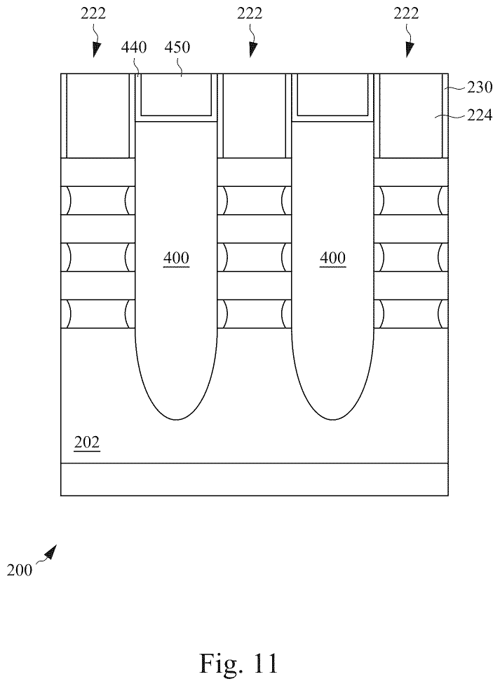

In FIG. 11, method 1000 includes, at operation S1120, capping the source/drain features 400 with dielectric. Specifically, a dielectric liner 440 may be formed over source/drain features 400 and along the sides of the spacers 230. Further, a dielectric 450 may be formed over the liner 440 over the source/drain features 400. Specifically, the gaps 234 are filled with dielectric 450. In exemplary embodiments, the dielectric 450 is a first interlayer dielectric layer (ILD). The dielectric 450 may be silicon oxide or other suitable dielectric material. In certain embodiments, the dielectric liner 440 is a dielectric, such as silicon nitride or another suitable material.

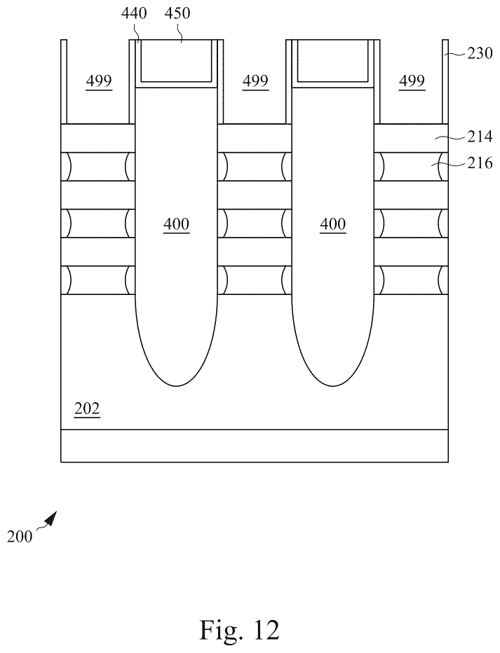

As further shown in FIG. 12, method 1000 includes, at operation S1130, opening and removing the sacrificial gate structures 222. Specifically, a chemical mechanical planarization (CMP) process may be performed to remove the mask layer 225 and to uncover the sacrificial gate electrode 224. Further, the sacrificial gate electrode 224 is removed to form gate cavities 499. As shown, the gate cavities 499 are bounded by the spacers 230 and by the uppermost epitaxial layer 214. FIG. 12 is an X-cut cross-sectional view.

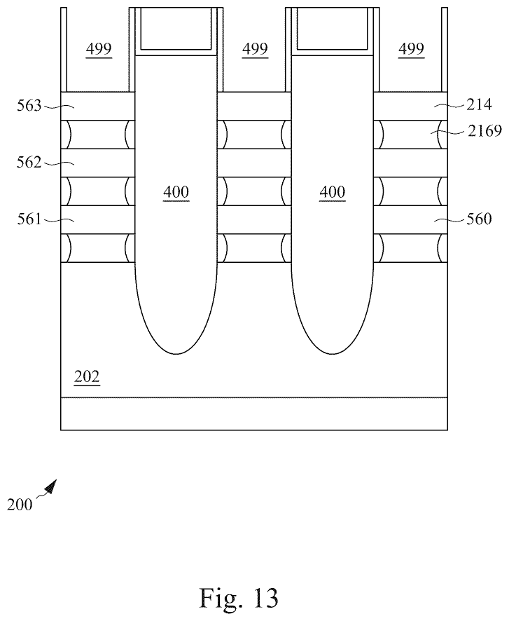

In FIG. 13, method 1000 removes the epitaxial layers 216 of the second composition at operation S1140. As a result, gaps 2169 are formed between the epitaxial layers 214 of the first composition. In this manner, the epitaxial layers 214 of the first composition are formed as vertically-spaced apart semiconductor nanosheets 560. The nanosheets 560 include a lowest nanosheet 561, a highest or uppermost nanosheet 563, and an intermediate nanosheet or nanosheets 562. FIG. 13 is an X-cut cross-sectional view.

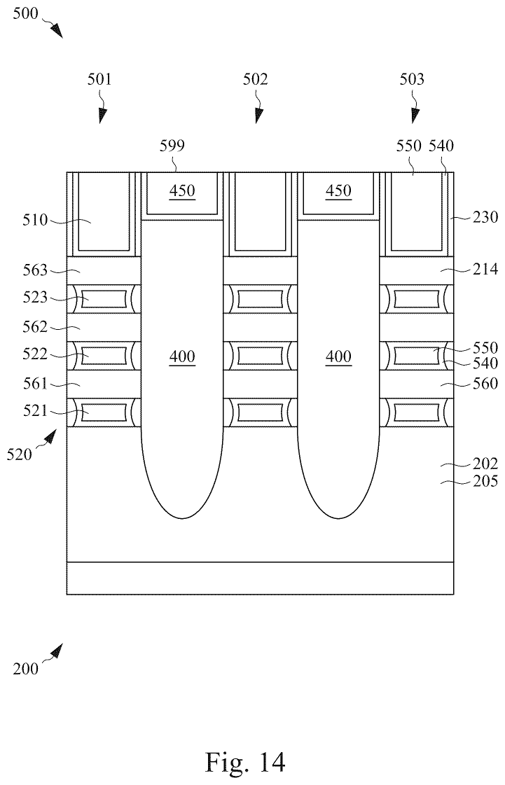

In FIG. 14, method 1000 includes, at operation S1150, completing a replacement metal gate process to form gate structures 500, such as gate structure 501, gate structure 502, and gate structure 503. FIG. 14 is an X-cut cross-sectional view.

In exemplary embodiments, the replacement metal gate process includes forming a gate dielectric layer 540 in the gate cavities 499 and in the gaps 2169, and forming a gate electrode material 550 over the gate dielectric layer 540 to fill the gate cavities 499 and fill the gaps 2169.

An exemplary gate dielectric layer(s) 540 is deposited conformally in the gate cavities 499 and gaps 2169. The gate dielectric 540 may be formed on the semiconductor nanosheets 560, and the gate electrode material 550 may be formed on the gate dielectric layer(s) 540. Thus, each semiconductor nanosheet 560 is wrapped in gate dielectric 540 and surrounded by gate electrode material 550.

In accordance with some embodiments, the gate dielectric layer(s) 540 comprises silicon oxide, silicon nitride, or multilayers thereof. In some embodiments, the gate dielectric layer(s) 540 is a high-k dielectric material, and in these embodiments, the gate dielectric layer(s) 540 may have a k value greater than about 7.0, and may include a metal oxide or a silicate of Hf, Al, Zr, La, Mg, Ba, Ti, Pb, and combinations thereof. The formation methods of the gate dielectric layer(s) 540 may include Molecular-Beam Deposition (MBD), ALD, PECVD, and the like.

The gate electrode material 550 is deposited over the gate dielectric layer(s) 540 and fills the remaining portion of the gate cavity. The gate electrode material 550 may be a metal-containing material such as TiN, TaN, TaC, Co, Ru, Al, combinations thereof, or multi-layers thereof. For example, although a single gate electrode material is illustrated, any number of work function tuning layers may be deposited.

As shown, the FIG. 14, the replacement metal gate process further includes removing excess portions of the gate dielectric layer(s) 540 and the gate electrode material 550 located over the top surface of the ILD 450. For example, a planarization process, such as a CMP process, may be performed to remove the excess portions of the gate dielectric layer(s) 540 and the gate electrode material 550. As a result, the device 200 has an upper surface 599. The remaining portions of material of the gate dielectric layer(s) 540 and the gate electrode material 550 thus form the replacement gate structure 500 of the resulting device 200. The gate dielectric layer(s) 540 and gate electrode material 550 may be collectively referred to as a “gate,” a “gate stack,” or a “gate structure.” Each gate structure 500 may extend along sidewalls of a channel region of the fin structures.

As shown in FIG. 14, each metal gate 500 includes an upper or outer gate portion 510 lying over the uppermost nanosheet 563. Further, each metal gate 500 includes inner gate portions 520 lying under the uppermost nanosheet 563. Specifically, each metal gate 500 includes an uppermost inner gate portion 523 lying directly under the uppermost nanosheet 563, a lowest inner gate portion 521 lying directly under the lowest nanosheet 561, and an intermediate inner gate portion 522 lying directly above the lowest nanosheet 561. Each metal gate 500 lies directly over a central portion 205 of the substrate 202.

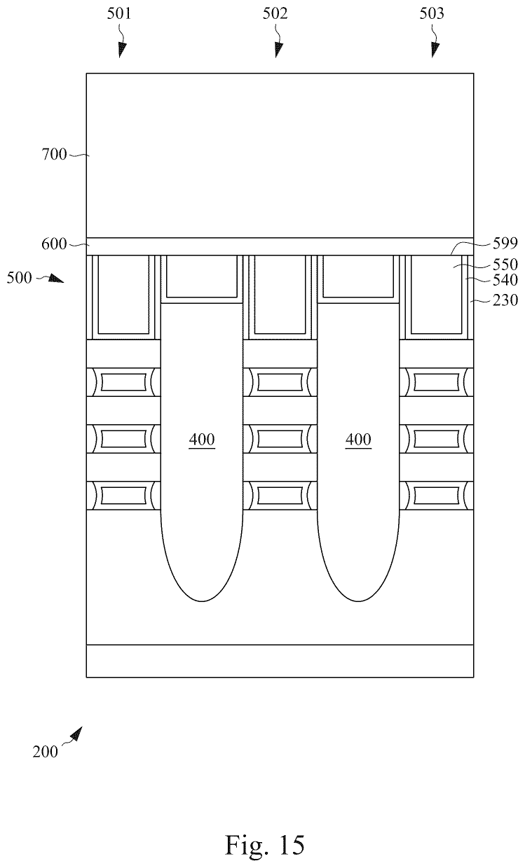

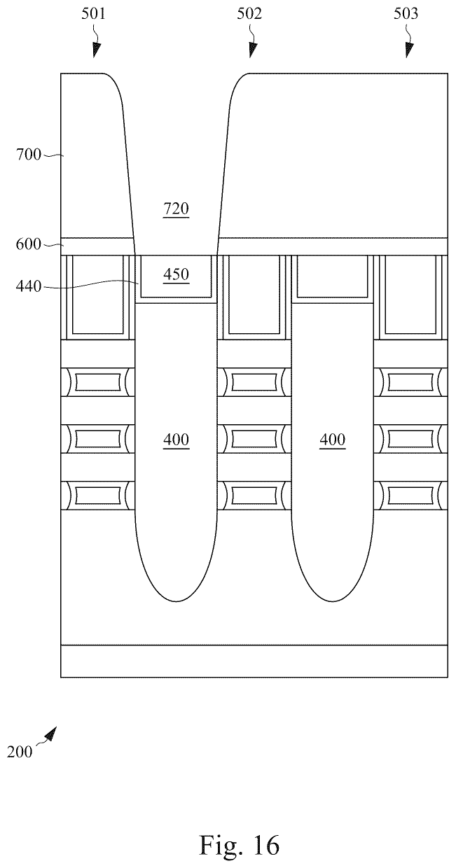

In FIG. 15, the method may include forming dielectric material over the device 200 at operation S1160. For example, a layer 600, such as a contact etch stop layer (CESL) or capping layer, may be formed over the surface 599. In exemplary embodiments, the layer 600 has a vertical thickness, in the Z-direction, of from one to five nanometers. FIG. 16 is an X-cut cross-sectional view.

Operation S1160 further includes forming a second interlayer dielectric (ILD) layer 700 over layer 600. In certain embodiments, the second interlayer dielectric (ILD) layer 700 is silicon oxide or another suitable material. In certain embodiments, the second ILD layer 700 and the first ILD layer 450 are the same material, for example silicon oxide.

At FIG. 16, method 1000 includes, at operation S1171, performing a first etch process to form an upper opening 720 over a selected source/drain feature 400. FIG. 16 is an X-cut cross-sectional view. As shown, the upper opening 720 is defined by sidewalls 730 formed by the ILD layer 700 and the layer 600.

In an exemplary embodiment, the first etch process may have an etch selectivity such that the layer 600 is removed at a faster or higher etch rate than the dielectric material 450. In an exemplary embodiment, the first etch process has an etch selectivity such that the layer 600 is removed at a faster or higher etch rate than the dielectric material 700. With the selected etch selectivity, the first etch process may be performed to land on the upper surface 599 of the dielectric 450 as shown.

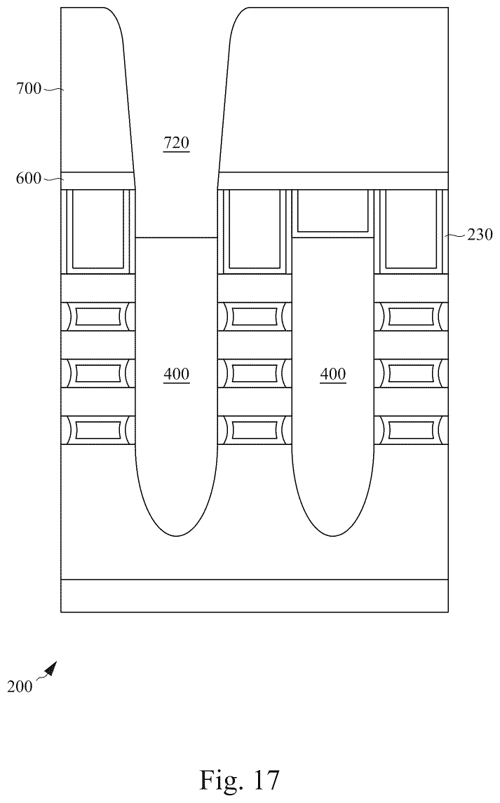

At FIG. 17, method 1000 includes, at operation S1172, performing a second etch process to remove the exposed portions of the liner 440 and dielectric 450 to extend the upper opening 720 to the selected source/drain feature 400. FIG. 17 is an X-cut cross-sectional view. As shown, the upper opening 720 is defined by sidewalls 730 formed by the ILD layer 700 and the layer 600, and the spacers 230.

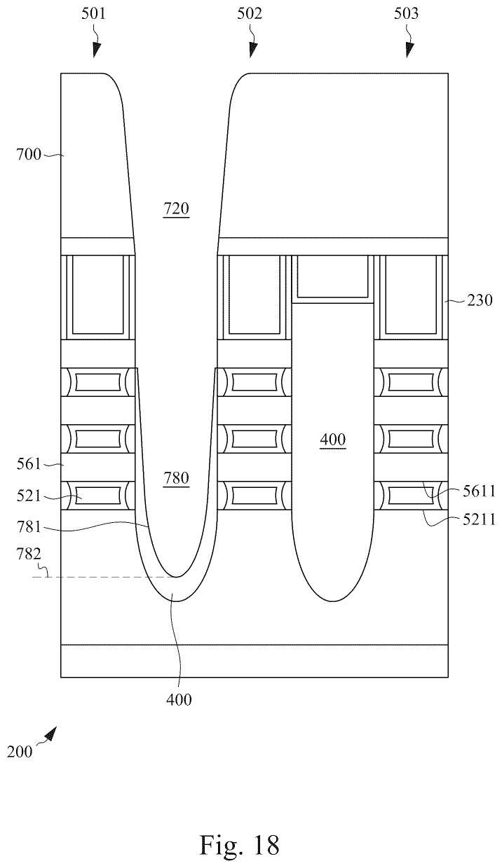

At FIG. 18, method 1000 includes, at operation S1173, performing a third etch process to form a trench 780 over and/or within a selected source/drain feature 400. FIG. 18 is an X-cut cross-sectional view. In the embodiment of FIG. 18, the trench 780 is formed with a bottom surface 781 having a U-shaped cross-section. The bottom surface 781 extends to a deepest point located at a horizontal plane 782, i.e., a plane extending in the X-and Y-directions at a constant Z-value. No portion of the trench 780 lies below the plane 782. As shown in FIG. 18, the horizontal plane 782 is located below, i.e., deeper than in the Z-direction, the lowest surface 5211 of the lowest inner gate portion 521, i.e., the lowest surface 5211 of each metal gate 501-503. Accordingly, the horizontal plane 782 is located below, i.e., deeper than in the Z-direction, the lowest surface 5611 of the lowest nanosheet 561 in each metal gate 501-503.

It is noted that while FIGS. 16-18 illustrate the opening and etching of one source/drain feature 400, this is only for ease of illustration. Adjacent source/drain features 400 may be opened and etched, and contacts formed therein according to the following processes, such that a gate 500 and nanosheets 560, and central portion 205 of substrate thereunder may be surrounded by two adjacent source/drain contacts 800 as described according to processes below.

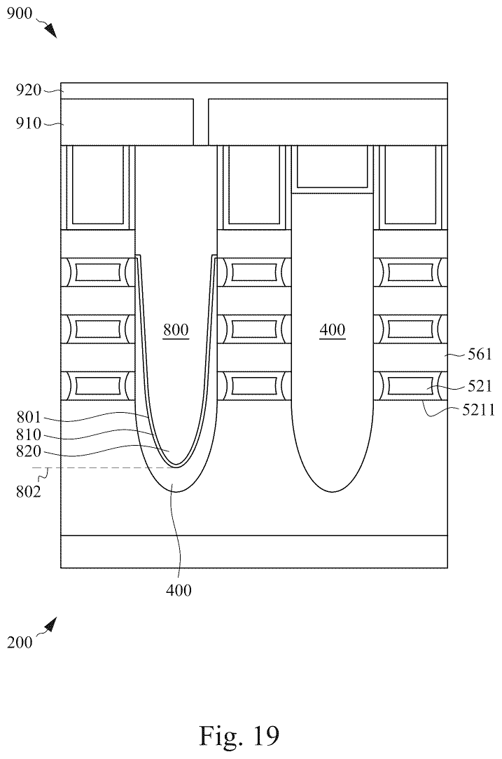

Referring to FIG. 19, the embodiment of FIG. 18 is processed further. Specifically, at operation S1180, method 1000 forms silicide 810 in the trench 780. Specifically, a silicide process may be performed to convert an upper portion 801 of the source/drain feature 400 to silicide 810. For example, a metal may be deposited in the trench and a thermal process may be performed to form the silicide 810.

Method 1000 may continue at operation S1190 with filling the trench 780 with a conductive material 820 as shown in FIG. 19. In certain embodiments, the conductive material(s) include metal(s), such as tungsten (W) or other suitable materials. A planarization process may be performed to remove an overburden portion of the conductive material 820 from over the dielectric 450. Operations S1180 and S1190 may form a conductive contact 800, i.e., source/drain contact 800, to selected source/drain feature(s) 400.

Method 1000 may continue at operation S1200 with further processing. For example, dielectric layer(s) 910 and metallization layer(s) 920 may be deposited and etched to form interconnect structures 900 as shown in FIG. 19. The further processing may include other back end of line (BEOL) processes such as passivation and packaging.

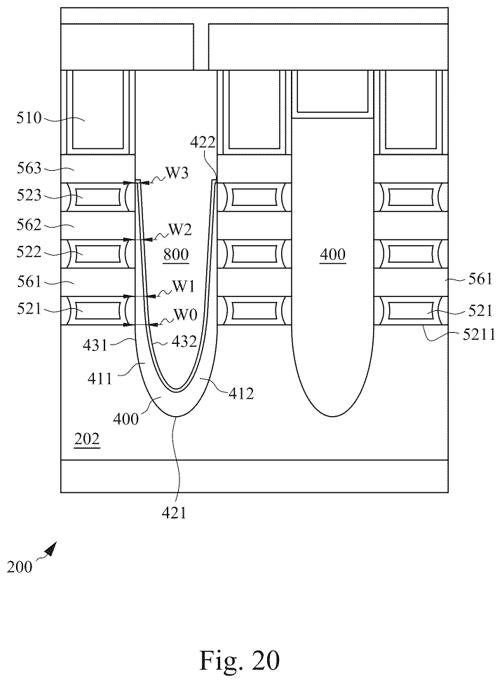

FIG. 20 focuses on a source/drain feature 400 adjacent to a gate 500 of the embodiment of FIG. 19. As shown in FIG. 20, the source/drain feature 400 has a U-shape cross-section with a lowest point 421. An inner horn 411 extends from the lowest point 421 to an upper end 422. Likewise, an outer horn 412 extends from the lowest point 421 to an upper end 422. The source/drain feature 400 has an outer surface 431 that contacts the substrate 202, gate portions (including spacers) 521, 522, 523, and 510 and nanosheets 561, 562, and 563. Further, the source/drain feature 400 has an inner surface 432 that contacts silicide or fill metal of the contact 800.

As shown in FIG. 20, the source/drain feature 400 has a lateral width W0, extending in the X-direction, from the outer surface 431 to inner surface 432 at the lowest surface of the lowest inner gate portion 521. In certain embodiments, width WO is from 10 to 20 nanometers. The source/drain feature 400 has a lateral width W1, extending in the X-direction, from the outer surface 431 to inner surface 432 at the interface of the lowest inner metal gate portion 521 and the lowest nanosheet 561. In certain embodiments, width W1 is from 0 to 20 nanometers, such as from 0 to 15 nanometers, 0 to 5 nanometers, or 0 to 2 nanometers. The source/drain feature 400 has a lateral width W2, extending in the X-direction, from the outer surface 431 to inner surface 432 at the interface of the intermediate inner metal gate portion 522 and the nanosheet 562. In certain embodiments, width W2 is from 0 to 5 nanometers, such as 0 to 2 nanometers. The source/drain feature 400 has a lateral width W3, extending in the X-direction, from the outer surface 431 to inner surface 432 at the interface of the uppermost inner metal gate portion 523 and the uppermost nanosheet 563. In certain embodiments, width W3 is from 0 to 2 nanometers. In certain embodiments, W0>W1>W2>W3.

As shown in FIG. 20, the horns 411 and 412 may not extend to the height of the outer metal gate portion 510. In other words, each upper end 422 may be located in a plane below the interface of the outer metal gate portion 510 and the uppermost nanosheet 563. In certain embodiments, each upper end 422 may be located in a plane below the interface of the uppermost nanosheet 563 and the uppermost inner gate portion 523. In certain embodiments, each upper end 422 may be located in a plane below the interface of the uppermost inner gate portion 523 and the nanosheet 562. In certain embodiments, each upper end 422 may be located in a plane below the interface of the nanosheet 562 and the inner gate portion 522. In certain embodiments, each upper end 422 may be located in a plane below the interface of the inner gate portion 522 and the nanosheet 561. In certain embodiments, each upper end 422 may be located in a plane below the interface of the nanosheet 561 and the inner gate portion 521. In certain embodiments, each upper end 422 may be located in a plane below the interface of the inner gate portion 521 and the substrate 202.

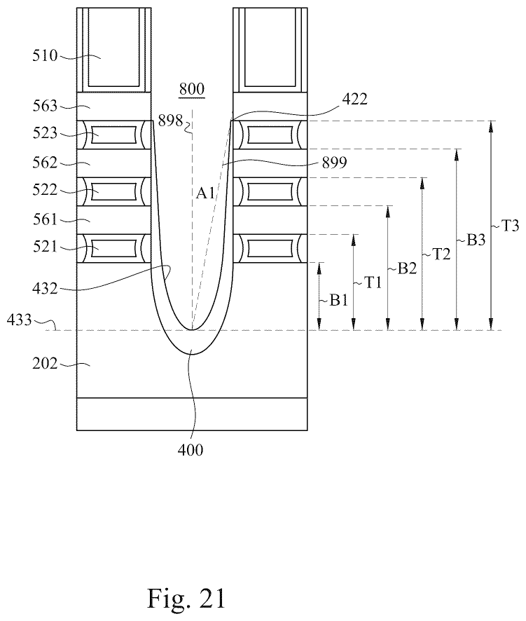

Referring now to FIG. 21, the structure of the source/drain feature 400 is described further. In FIG. 21, the metal fill 820 and silicide 810 are shown collectively as contact 800. In FIG. 21, the inner surface 432 of the source/drain feature 400 has a lowest point at a horizontal plane 433 defined by the Y-and X-axes at a constant height in the Z-direction. Plane 433 also defines the lowest point of the contact 800, defined by the lowest point of the silicide.

As shown, plane 433 is located at a vertical distance B1, in the Z-direction from the interface of the substrate 202 and the inner gate portion 521. In certain embodiments, vertical distance B1 is from 5 to 30 nanometers.

Plane 433 is located at a vertical distance T1, in the Z-direction from the interface of the inner gate portion 521 and nanosheet 561. In certain embodiments, vertical distance T1 is from 15 to 35 nanometers.

Plane 433 is located at a vertical distance B2, in the Z-direction from the interface of the nanosheet 561 and the inner gate portion 522. In certain embodiments, vertical distance B2 is from 20 to 40 nanometers.

Plane 433 is located at a vertical distance T2, in the Z-direction from the interface of the inner gate portion 522 and nanosheet 562. In certain embodiments, vertical distance T2 is from 30 to 50 nanometers.

Plane 433 is located at a vertical distance B3, in the Z-direction from the interface of the nanosheet 562 and the inner gate portion 523. In certain embodiments, vertical distance B3 is from 40 to 60 nanometers.

Plane 433 is located at a vertical distance T3, in the Z-direction from the interface of the inner gate portion 523 and nanosheet 563. In certain embodiments, vertical distance T3 is from 50 to 70 nanometers.

As further shown in FIG. 21, the source/drain feature 400 is formed with an angle A1 from a vertical centerline 898 passing through the lowest point of the inner surface 432 and a line 899 from the lowest point of the inner surface 432 to the upper end 422. In certain embodiments, angle A1 is from 20 to 85 degrees.

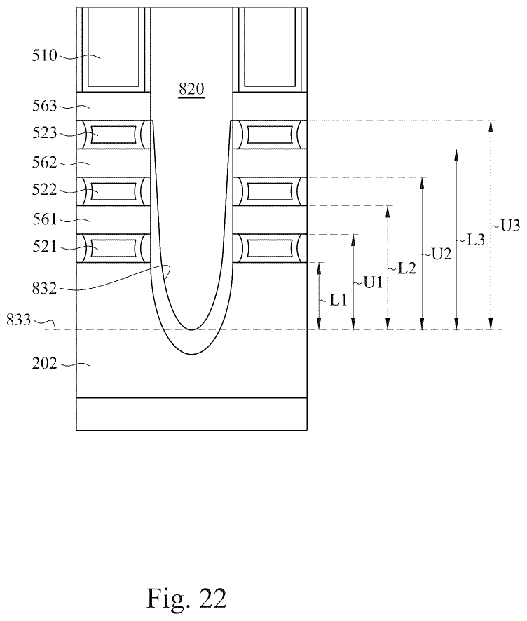

Referring now to FIG. 22, the structure of the metal fill 820 of the contact 800 is described further. In FIG. 22, the silicide 810 and source/drain feature 400 are not shown. The metal fill 820 has an outer surface 832. As shown, the outer surface 832 of the metal 820 of contact 800 has a lowest point at a horizontal plane 833 defined by the Y-and X-axes at a constant height in the Z-direction.

As shown, plane 833 is located at a vertical distance L1, in the Z-direction from the interface of the substrate 202 and the inner gate portion 521. In certain embodiments, vertical distance L1 is from 0 to 20 nanometers.

Plane 833 is located at a vertical distance U1, in the Z-direction from the interface of the inner gate portion 521 and nanosheet 561. In certain embodiments, vertical distance U1 is from 10 to 30 nanometers.

Plane 833 is located at a vertical distance L2, in the Z-direction from the interface of the nanosheet 561 and the inner gate portion 522. In certain embodiments, vertical distance L2 is from 15 to 35 nanometers.

Plane 833 is located at a vertical distance U2, in the Z-direction from the interface of the inner gate portion 522 and nanosheet 562. In certain embodiments, vertical distance U2 is from 25 to 45 nanometers.

Plane 833 is located at a vertical distance L3, in the Z-direction from the interface of the nanosheet 562 and the inner gate portion 523. In certain embodiments, vertical distance L3 is from 35 to 55 nanometers.

Plane 433 is located at a vertical distance U3, in the Z-direction from the interface of the inner gate portion 523 and nanosheet 563. In certain embodiments, vertical distance U3 is from 45 to 65 nanometers.

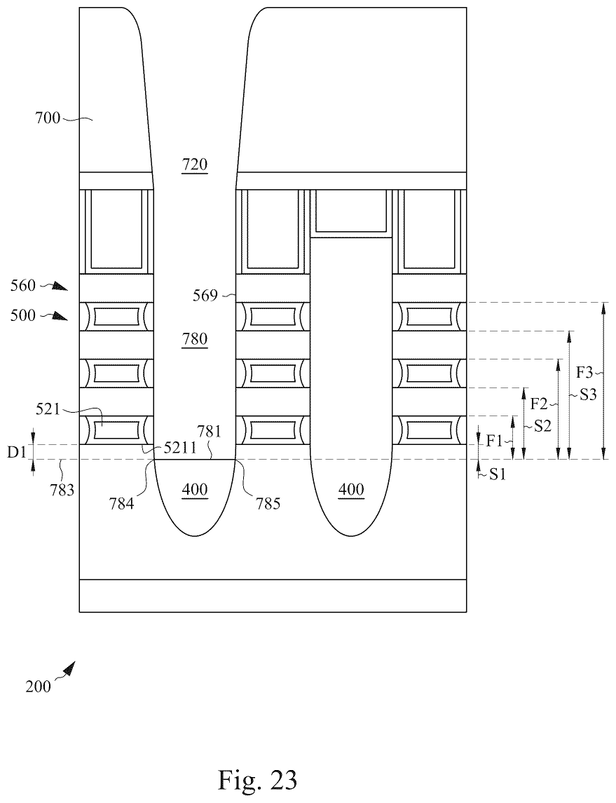

FIG. 23 illustrates another embodiment in which the third etch process of operation S1173 forms a trench 780 over and/or within a selected source/drain feature 400. FIG. 23 is an X-cut cross-sectional view. In the embodiment of FIG. 23, the trench 780 is formed with a bottom surface 781 that may have a substantially linear cross-section. As shown in FIG. 23, a horizontal plane 783 is defined by a highest point of the bottom surface 781, i.e., no portion of the source/drain feature 400 is located above the plane 783.

As shown, the bottom surface 781 terminates at a first end 784 and at a second end 785. The bottom surface 781 may have a height differential of from 0 to 15 nanometers from the first end 784 to the second end 785.

As shown in FIG. 23, plane 783 may be formed at a distance D1 below the lowest surface 5211 of the gate 500, i.e., the lowest surface 5211 of the inner gate portion 521. In certain embodiments, distance D1 is from 0 to 15 nanometers, such as from 0 to 10 nanometers.

The third etch of operation S1173 may be performed in a single process or in multiple processes. In certain embodiments, the third etch includes a dry etch, such as a capacitively coupled plasma (CCP) or inductively coupled plasma (ICP) etch. In certain embodiments, the dry etch is performed with a gas selected from C₄F₆ or C₄F₈. In certain embodiments, the dry etch is a high pressure plasma dry etch. For example, the dry etch may be performed at a pressure of from 10 to 500 millitorr (mTorr). In certain embodiments, the dry etch is performed at a temperature of from negative thirty (−30) to 140 degrees Celsius.

In certain embodiments, the third etch additionally or alternatively includes a wet etch. For example, the wet etch may be performed with an etchant such as dilute NH₄OH. In certain embodiments, the wet etch is performed at a temperature of from 20 to 100 degrees Celsius.

Collectively, the first etch process of operation S1171, the second etch process of operation S1172, and the third etch process of operation S1173 represent an operation S1170 of opening and forming a trench 780 over the selected source/drain feature 400. In certain embodiments, operations S1171, S1172, and/or S1173 may be combined into one or two processes. For example, the etch used to form the trench 780 may also remove the dielectric 440/450 above the source/drain feature 400.

As shown, plane 783 is located at a vertical distance S1, in the Z-direction from the interface of the substrate 202 and the inner gate portion 521. In certain embodiments, vertical distance S1 is from 0 to 20 nanometers.

Plane 783 is located at a vertical distance F1, in the Z-direction from the interface of the inner gate portion 521 and nanosheet 561. In certain embodiments, vertical distance F1 is from 10 to 30 nanometers.

Plane 783 is located at a vertical distance S2, in the Z-direction from the interface of the nanosheet 561 and the inner gate portion 522. In certain embodiments, vertical distance S2 is from 15 to 35 nanometers.

Plane 783 is located at a vertical distance F2, in the Z-direction from the interface of the inner gate portion 522 and nanosheet 562. In certain embodiments, vertical distance F2 is from 25 to 45 nanometers.

Plane 783 is located at a vertical distance S3, in the Z-direction from the interface of the nanosheet 562 and the inner gate portion 523. In certain embodiments, vertical distance S3 is from 35 to 55 nanometers.

Plane 783 is located at a vertical distance F3, in the Z-direction from the interface of the inner gate portion 523 and nanosheet 563. In certain embodiments, vertical distance F3 is from 45 to 65 nanometers.

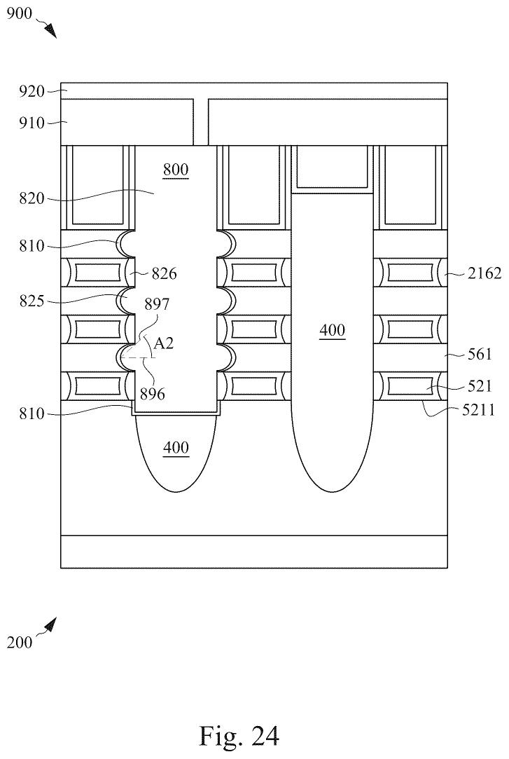

Referring to FIG. 24, the embodiment of FIG. 23 is processed further. Specifically, at operation S1180, method 1000 forms silicide 810 in the trench 780. Specifically, a silicide process may be performed to convert an upper portion of the source/drain feature 400 to silicide 810. For example, a metal may be deposited in the trench and a thermal process may be performed to form the silicide 810.

Method 1000 may continue at operation S1190 with filling the trench 780 with a conductive material 820 as shown in FIG. 24. In certain embodiments, the conductive material(s) include metal(s), such as tungsten (W) or other suitable materials. A planarization process may be performed to remove an overburden portion of the conductive material 820 from over the dielectric 450. Operations S1180 and S1190 may form a conductive contact 800, i.e., source/drain contact 800, to selected source/drain feature(s) 400.

Method 1000 may continue at operation S1200 with further processing. For example, dielectric layer(s) 910 and metallization layer(s) 920 may be deposited, planarized and etched to form interconnect structures 900 as shown in FIG. 24. The further processing may include other back end of line (BEOL) processes such as passivation and packaging.

As shown, in the embodiment of FIGS. 23-24, the sidewalls 569 of the nanosheets 560 are not covered by the source/drain feature 400 when the silicide process is performed. Therefore, the sidewalls 569 of the nanosheets 560 may be recessed and converted to silicide as shown in FIG. 24. Then, when the metal fill 820 is formed, projections 825 of the metal fill 820 fill the recessed sidewalls 569. The projections 825 extend outward from wall portions 826 of the metal fill 820 that abut the inner spacers 2162.

Each laterally-extending projection 825 may be formed with an angle A2 from a horizontal centerline 896 passing through the outward-most point of the projection 825 and a line 897 from the outward-most point of the projection 825 to the junction with the vertical wall portion 826. In certain embodiments, angle A1 is from 20 to 85 degrees.

Each embodiment provides for formation of channel regions 560 directly between source/drain contacts 800 such that current paths may be completely horizontal from the source/drain contact 800, through the respective channel region 560, to the other source/drain contact 800. Further, embodiments herein may reduce or eliminate source/drain feature material from between the source/drain contact 800 and the channel regions 560.

In an embodiment, a method includes forming a stack of semiconductor nanosheets over a substrate; forming a source/drain feature adjacent to the stack; etching a portion of the source/drain feature to form a trench, wherein the trench extends to a horizontal plane at or below a lowest surface of a lowest semiconductor nanosheet in the stack; and forming a conductive contact to the source/drain feature in the trench.

In certain embodiments of the method, the lowest semiconductor nanosheet in the stack of semiconductor nanosheets is located over a lowest inner metal gate portion; and the conductive contact is located laterally adjacent to the lowest inner metal gate portion.

In certain embodiments of the method, the lowest semiconductor nanosheet in the stack of semiconductor nanosheets is located over a lowest inner metal gate portion; and the horizontal plane is located below a lowest surface of the lowest inner metal gate portion.

In certain embodiments of the method, the horizontal plane is from 0 to 30 nanometers below the lower surface of the lowest semiconductor nanosheet in the stack.

In certain embodiments of the method, the horizontal plane is from 5 to 30 nanometers below the lower surface of the lowest semiconductor nanosheet in the stack.

In certain embodiments of the method, after forming the conductive contact to the source/drain feature in the trench, no portion of the source/drain feature is located between the conductive contact and the stack of semiconductor nanosheets.

In certain embodiments of the method, after forming the conductive contact to the source/drain feature in the trench, a respective remaining portion of the source/drain feature is located between the conductive contact and at least one of the semiconductor nanosheets in the stack of semiconductor nanosheets, and a lateral width of each remaining portion is no more than 15 nanometers.

In certain embodiments of the method, etching the portion of the source/drain feature to form the trench includes performing a plasma dry etch at a pressure of at least 10 millitorr; and/or performing a wet etch.

In another embodiment, a semiconductor structure is provided and includes a substrate; a gate structure having a lowest surface overlying a central portion of the substrate; a first source/drain feature and a second source/drain feature surrounding the central portion of the substrate; a first source/drain contact over the first source/drain feature; and a second source/drain contact over the second source/drain feature; and the lowest surface of the gate structure is located directly between the first source/drain contact and the second source/drain contact.

In certain embodiments of the semiconductor structure, each source/drain feature has a U-shaped cross-section including an outer horn and an inner horn, and the inner horn is adjacent to the gate structure and is located between the gate structure and the outer horn.

In certain embodiments of the semiconductor structure, the gate structure includes an outer gate portion overlying a stack of vertically spaced inner gate portions separated by semiconductor nanosheets; each horn has a lateral thickness adjacent to the lowest surface of from 10 to 20 nanometers; and each horn has a lateral thickness adjacent to an uppermost inner gate portion of from 0 to 2 nanometers.

In certain embodiments of the semiconductor structure, each source/drain feature has an uppermost surface extending from an inner side surface nearest the gate structure to an outer side surface farthest from the gate structure, and the uppermost surface is located at or below the lowest surface of the gate structure.

In certain embodiments of the semiconductor structure, the uppermost surface is located at a vertical distance from the lowest surface of the gate structure of from 0 to 10 nanometers.

In certain embodiments of the semiconductor structure, the gate structure includes an outer gate portion overlying a stack of vertically spaced inner gate portions separated by semiconductor nanosheets; each source/drain contact includes a sidewall nearest the gate structure; and each source/drain contact includes projections extending laterally from the sidewall toward the semiconductor nanosheets.

In certain embodiments of the semiconductor structure, each projection has a rounded exterior surface formed with an angle of 20 to 85 degrees.

In another embodiment, a semiconductor structure is provided and includes a gate-all-around (GAA) structure including an outer gate portion overlying a stack of vertically spaced inner gate portions separated by semiconductor nanosheets; a vertically-extending metal contact located laterally adjacent to the outer gate portion and the stack of vertically spaced inner gate portions; wherein the stack of vertically spaced inner gate portions includes an uppermost inner gate portion; and wherein from 0 to 2 nanometers of epitaxial material is located directly between the uppermost inner gate portion and the vertically-extending metal contact.

In certain embodiments of the semiconductor structure, the stack of vertically spaced inner gate portions includes a lowest inner gate portion; and from 0 to 20 nanometers of epitaxial material is located directly between the lowest inner gate portion and the vertically-extending metal contact.

In certain embodiments of the semiconductor structure, the stack of vertically spaced inner gate portions includes a lowest inner gate portion; no epitaxial material is located directly between the uppermost inner gate portion and the vertically-extending metal contact; and no epitaxial material is located directly between the lowest inner gate portion and the vertically-extending metal contact.

In certain embodiments of the semiconductor structure, the vertically-extending metal contact has a bottom surface having a U-shaped cross-section formed with an angle of from 20 to 85 degrees.

In certain embodiments of the semiconductor structure, the vertically-extending metal contact includes a sidewall nearest the GAA structure; and the vertically-extending metal contact includes projections extending laterally from the sidewall toward the semiconductor nanosheets.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of semiconductor nanosheets over a substrate;
forming a source/drain feature adjacent to the stack;
etching a portion of the source/drain feature to form a trench, wherein the trench extends to a horizontal plane at or below a lowest surface of a lowest semiconductor nanosheet in the stack; and
forming a conductive contact to the source/drain feature in the trench.

2. The method of claim 1, wherein:
the lowest semiconductor nanosheet in the stack of semiconductor nanosheets is located over a lowest inner metal gate portion; and
the conductive contact is located laterally adjacent to the lowest inner metal gate portion.

3. The method of claim 1, wherein:
the lowest semiconductor nanosheet in the stack of semiconductor nanosheets is located over a lowest inner metal gate portion; and
the horizontal plane is located below a lowest surface of the lowest inner metal gate portion.

4. The method of claim 1, wherein the horizontal plane is from 0 to 30 nanometers below the lowest surface of the lowest semiconductor nanosheet in the stack.

5. The method of claim 1, wherein the horizontal plane is from 5 to 30 nanometers below the lowest surface of the lowest semiconductor nanosheet in the stack.

6. The method of claim 1, wherein, after forming the conductive contact to the source/drain feature in the trench, no portion of the source/drain feature is located between the conductive contact and the stack of semiconductor nanosheets.

7. The method of claim 1, wherein, after forming the conductive contact to the source/drain feature in the trench, a respective remaining portion of the source/drain feature is located between the conductive contact and at least one of the semiconductor nanosheets in the stack of semiconductor nanosheets, wherein a lateral width of each remaining portion is no more than 15 nanometers.

8. The method of claim 1, wherein etching the portion of the source/drain feature to form the trench comprises:
performing a plasma dry etch at a pressure of at least 10 millitorr; and/or
performing a wet etch.

9. A semiconductor structure comprising:
a substrate;
a gate structure having a lowest surface overlying a central portion of the substrate;
a first source/drain feature and a second source/drain feature surrounding the central portion of the substrate;
a first source/drain contact over the first source/drain feature; and
a second source/drain contact over the second source/drain feature;
wherein the lowest surface of the gate structure is located directly between the first source/drain contact and the second source/drain contact.

10. The semiconductor structure of claim 9, wherein each source/drain feature has a U- shaped cross-section including an outer horn and an inner horn, wherein the inner horn is adjacent to the gate structure and is located between the gate structure and the outer horn.

11. The semiconductor structure of claim 10, wherein:
the gate structure includes an outer gate portion overlying a stack of vertically spaced inner gate portions separated by semiconductor nanosheets;
each horn has a lateral thickness adjacent to the lowest surface of from 10 to 20 nanometers; and
each horn has a lateral thickness adjacent to an uppermost inner gate portion of from 0 to 2 nanometers.

12. The semiconductor structure of claim 9, wherein each source/drain feature has an uppermost surface extending from an inner side surface nearest the gate structure to an outer side surface farthest from the gate structure, and wherein the uppermost surface is located at or below the lowest surface of the gate structure.

13. The semiconductor structure of claim 12, wherein the uppermost surface is located at a vertical distance from the lowest surface of the gate structure of from 0 to 10 nanometers.

14. The semiconductor structure of claim 12, wherein:
the gate structure includes an outer gate portion overlying a stack of vertically spaced inner gate portions separated by semiconductor nanosheets;
each source/drain contact includes a sidewall nearest the gate structure; and
each source/drain contact includes projections extending laterally from the sidewall toward the semiconductor nanosheets.

15. The semiconductor structure of claim 14, wherein each projection has a rounded exterior surface formed with an angle of 20 to 85 degrees.

16. A semiconductor structure comprising:
a gate-all-around (GAA) structure including an outer gate portion overlying a stack of vertically spaced inner gate portions separated by semiconductor nanosheets; and
a vertically-extending metal contact located laterally adjacent to the outer gate portion and the stack of vertically spaced inner gate portions;
wherein the stack of vertically spaced inner gate portions includes an uppermost inner gate portion; and
wherein from 0 to 2 nanometers of epitaxial material is located directly between the uppermost inner gate portion and the vertically-extending metal contact.

17. The semiconductor structure of claim 16, wherein:
the stack of vertically spaced inner gate portions includes a lowest inner gate portion; and
from 0 to 20 nanometers of epitaxial material is located directly between the lowest inner gate portion and the vertically-extending metal contact.

18. The semiconductor structure of claim 16, wherein:
the stack of vertically spaced inner gate portions includes a lowest inner gate portion;
no epitaxial material is located directly between the uppermost inner gate portion and the vertically-extending metal contact; and
no epitaxial material is located directly between the lowest inner gate portion and the vertically-extending metal contact.

19. The semiconductor structure of claim 16, wherein the vertically-extending metal contact has a bottom surface having a U-shaped cross-section formed with an angle of from 20 to 85 degrees.

20. The semiconductor structure of claim 16, wherein:
the vertically-extending metal contact includes a sidewall nearest the GAA structure; and
the vertically-extending metal contact includes projections extending laterally from the sidewall toward the semiconductor nanosheets.
